(19) United States
(12) Patent Application Publication
(10) Pub. No.: US 2007/0205498 A1
(43) Pub. Date: Sep. 6, 2007

(54) Signal Routing in a Multilayered Printed Circuit Board

(75) Inventors: Srdjan Djordjevic, Munich (DE); Peter Oeschay, Wehringen (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA NORTH AMERICA CORP., Cary, NC (US)

(21) Appl. No.: 11/611,388

(22) Filed: Dec. 15, 2006

Related U.S. Application Data
(60) Provisional application No. 60/778,066, filed on Mar. 2, 2006.

(51) Int. Cl. H01L 23/04

(52) U.S. Cl. 257/698

(57) ABSTRACT

A signal routing technique for a multilayered printed circuit board is provided. The multilayered printed circuit board comprises a top layer, a bottom layer and at least one internal layer. Signals for a first subset of a plurality of higher speed buses are routed in stripline on the first internal layer. Signals for a second subset of said plurality of higher speed buses in microstrip on the top layer.

### RELATED APPLICATION

The application claims priority to U.S. Provisional Patent Application No. 60/778,066, filed Mar. 2, 2006, the entirety of which is incorporated herein by reference.

### BACKGROUND OF THE INVENTION

Multilayered printed circuit boards (PCBs) are used to contain a plurality of electrical circuits or devices, such as integrated circuit devices, in a single package or unit. A multilayered PCB comprises a top layer, a bottom layer and one or more internal layers.

One application of a multilayered printed circuit board (PCB) is dual in-line memory module (DIMM). Semiconductor memory components are arranged on top and bottom layers of the PCB. The semiconductor memory components are driven by a signal driver/control component arranged in the center of the PCB. This control component is commonly referred to as the “hub” or advanced memory buffer (AMB).

When a plurality of DIMMs is arranged in a daisy-chain configuration, signals are routed from a memory controller to the chain of DIMMs and to the memory controller from the chain of DIMMs. Thus, signals must be propagated through the chain to and from a memory chip on a DIMM in the chain.

In a planar DIMM design with two or more rows of memory components or chips (e.g., DRAMs), the chips are mounted on the top and bottom layers of the PCB. Therefore, there is insufficient space on the top layer to route all the signals. While various techniques have been employed to overcome the space scarcity issues, none of those techniques is applicable to very high speed signal applications.

Accordingly, a technique is needed for routing certain signal lines on a multilayered printed circuit board in order to achieve higher bus speeds.

### SUMMARY OF THE INVENTION

Briefly, a signal routing technique for a multilayered printed circuit board is provided. The multilayered printed circuit board comprises a top layer, a bottom layer and at least one internal layer. Signals for a first subset of a plurality of higher speed buses are routed in stripline on the first internal layer. Signals for a second subset of said plurality of higher speed buses in microstrip on the top layer.

Objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 is an enlarged cross-sectional view of a multilayered PCB according to an embodiment of the invention.

FIG. 2 is a schematic diagram of a system comprising several multilayered PCBs shown in FIG. 1 according to an embodiment of the invention.

FIGS. 3-5 are enlarged images of a portion of a top layer of a multilayered PCB according to an embodiment of the invention.

FIG. 6 is an enlarged image of a portion of an internal layer of a multilayered PCB according to an embodiment of the invention.

FIG. 7 is a graphical plot showing a comparison of crosstalk simulation results for two adjacent high speed signal bus lines routed using microstrip techniques and the same two adjacent lines routed using stripline techniques according to an embodiment of the invention.

### DETAILED DESCRIPTION

According to an embodiment of the invention, several of the longer (in physical length) differential signals lines of higher speed buses on a multilayered printed circuit board (PCB), such as a DIMM, are routed in an internal layer in stripline rather than in microstrip. By moving some of the higher speed signal bus lines to an internal layer, space is freed up on the top layer to position vias farther away from each other than would be otherwise possible if all of these signal bus lines are routed on the top layer. In addition, by routing some of the longest differential signal lines in stripline (as opposed to microstrip), better differential impedance tolerance is achieved for those buses. The lower reflective noise that results from this arrangement together with the reduced cross talk achieves a desirable larger “eye” opening of the signals and is useful for higher signal bus speeds in a multilayered PCB.

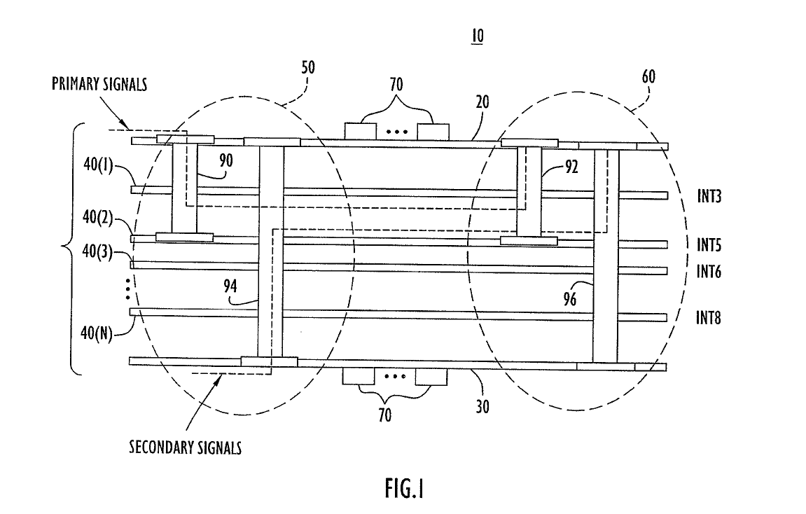

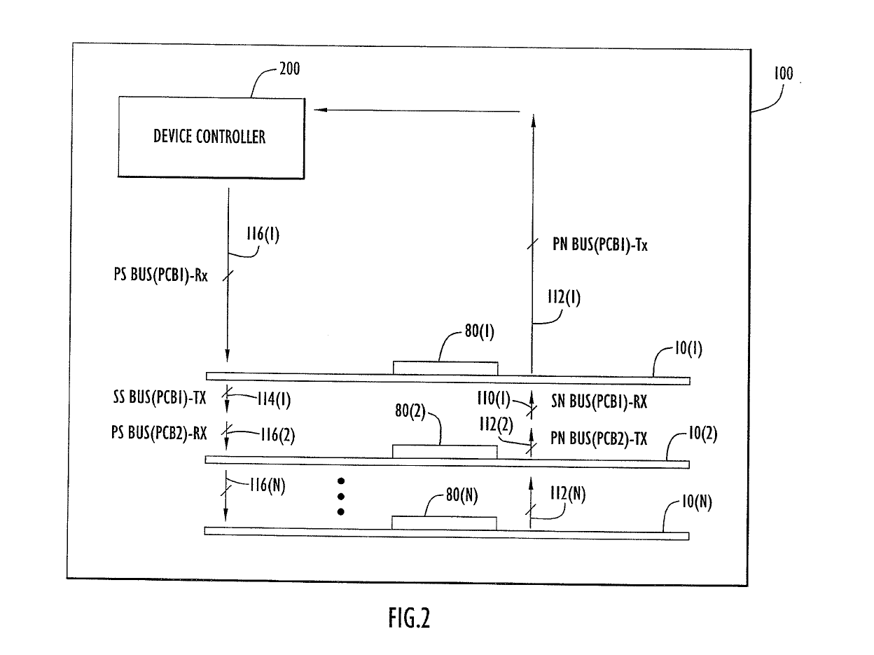

Referring first to FIGS. 1 and 2, a signal routing technique according to an embodiment of the present invention is described in further detail. A multilayered PCB 10 is provided comprising a top layer 20, bottom layer 30 and one or more internal layers 40(1) to 40(N). On the top layer 20, bottom layer 30 and internal layers 40(1) to 40(N) there are separate and designated surface areas called a connector area 50 and a hub area 60. The connector area 50 is dedicated to making connections to and from external devices in the case of the top layer 20 and bottom layer 30. The hub area 60 of a layer (top, bottom and intermediate) is where a control component or advanced memory buffer (AMB) is located. In an embodiment in which the multilayered PCB 10 is a DIMM, such as a FBDIMM, there are multiple memory chips or integrated circuits 70 on the top layer 20 and bottom layer 30.

FIG. 2 shows an embodiment in which a plurality of multilayered PCBs of the embodiment shown in FIG. 1 shown at reference numerals 10(1) to 10(N) are mounted to a base circuit board 100, sometimes called a motherboard, and connected in a series or daisy-chain configuration. That is, signals are transferred between the top layer of one PCB and the bottom layer of the adjacent PCB in one direction, and between the bottom layer of one PCB and the top layer of the adjacent PCB in the other direction. In one embodiment, each of the PCBs 10(1) to 10(N) may be a DIMM. Also shown in FIG. 2 is a control component or hub 80(i) on each PCB 10(i). A device controller 200 connects to and supplies signals to and receives signals from the PCBs 10(1) to 10(N). In one embodiment, the device controller 200 may be a memory controller. The device controller 200 may be on the same base circuit board 100 as shown in FIG. 2 or external to the base circuit board 100.

The base circuit board 100 has connector slots or other connection structures that receive each of PCBs 10(1) to 10(N) and include contacts that make connections to pads on the top layer and bottom layer of each PCB. For simplicity, these connection slots are not shown in FIG. 2. The base circuit board 100 further comprises signal lines, called buses, that route signals between adjacent PCBs and between the PCB 10(1) that is closest in physical proximity to the device controller 200. These buses are conductive lines or traces on the base circuit board 100 that extend between connectors slots and between the connector slot for PCB 10(1) and the device controller. Each PCB comprises signal lines that connect to the buses on the base circuit board 100 by way of the connection between the PCB contact pads on the top and bottom layers and the connector slots on the base circuit board 100.

According to one embodiment, signal lines on the base circuit board 100 that route signals in a direction towards the memory controller 100 from a PCB are called “northbound” buses and signal lines that route signals in a direction away from the memory controller 100 are called “southbound” buses. In addition, signal lines on the base circuit board that route signals to or from a top layer of a PCB are called “primary” buses and signal lines on the base circuit board 100 that route signals to or from a bottom layer of a PCB are called “secondary” buses. For example, between PCB 10(1) and PCB 10(2), in the northbound direction there is a primary northbound (PN) bus on the base circuit board 100, called PN bus(PCB2) represented by the arrow 110(1) that receives signals from the top layer of PCB 10(2) on the secondary northbound (SN) bus on PCB 10(1) called SN bus(PCB1) represented by arrow 112(2). Similarly, in the southbound direction, there is a secondary southbound (SS) bus called SS bus(PCB1) represented by arrow 114(1) that routes signals from the bottom layer of PCB 10(1) to the primary southbound (PS) bus called PS bus(PCB2) that is coupled to the top layer of PCB 10(2). In general, for each PCB 10(i), there is a SN bus 110(i), a PN bus 112(i), a SS bus 114(i) and a PS bus 116(i), for i=1 to N, except that for the last PCB 10(N) in the chain, a SS bus and a SN bus are not needed.

For the PCB 10(1) that is closest in the chain to the device controller 200, the PN bus 112(1) on the base circuit board 100 routes signals to the device controller 200 and is often the longest signal path in physical length. Each PCB has a limited amount of power that it can use to drive signals out from its top and bottom layers and therefore the PCB that is placed in the position corresponding to PCB 10(1) must be capable of driving signals over the longer signal path of the PN bus 112(1) to the device controller 200. Thus, the PN bus 112(1) has a greater amount of loss because its overall impedance is increased due to its longer length. For applications that require higher speed (or are otherwise speed-sensitive to the) transfer of data to and from the chain of PCBs, the PN bus 112(1) has the biggest impact on power consumption and timing budgets. The PS bus 116(1) also has a relatively long signal path, but it is not as critical as the signal path of the PN bus 112(1) because the device controller 200 is driving signals to the PS bus 116(1) and the availability of power for the device controller 200 is not as limited as it is for the PCBs. In addition, on some PCB designs, there are more PN differential bus lines than PS differential bus lines. Consequently, the PN differential bus lines may have greater crosstalk since there are more of them, even if the physical length of the PN differential bus lines are not greater than the PS bus differential lines. The PCBs may be manufactured using a common design and fabrication process and therefore each PCB needs to be capable of supplying signals to the longer PN bus 112(1) and receiving signals from the PS bus 116(1) without degradation of performance since any one of the PCBs so manufactured may be deployed in the position closest to the device controller 200, e.g., the position of PCB 10(1).

With reference back to FIG. 1 in conjunction with FIG. 2, according to an embodiment of the invention, the routing within a PCB 10 of one or more of the longer signal lines that, if placed in the position of PCB 10(1) in a chain of PCBs as shown in FIG. 2, would connect to the PN bus 112(1) and/or to the PS bus 116(1), is configured to minimize signal loss and cross talk so as to preserve timing and power consumption performance for data rate (i.e., speed) sensitive applications. In one embodiment, one or more of the longer signal lines that would otherwise be routed on the top layer 20 of the PCB 10 in microstrip form are instead routed on an internal layer, such as internal layer 40(1), in stripline form. Thus, signal lines for a first subset of a plurality higher speed buses are implemented in stripline on a first internal layer, e.g., internal layer 40(1).

In one embodiment, first partial or “blind” vias 90 are provided at the connector area 50 that extend through internal layer 40(1) to layer 40(2), as an example. The first subset of the plurality of higher speed buses, those signal lines that are longer in physical length among the signal lines for the higher speed buses, are routed on the internal layer 40(1) to the hub area 60 and then transported back up to the top layer 20 by second partial vias 92. Primary signals to and from the PCB are routed on the internal layer 40(1). Signal lines for a second subset of the plurality of higher speed buses (for primary signals), those signals lines that are shorter, are routed on the top layer in microstrip. Signal lines for a third subset of the plurality of higher speed buses (for secondary signals) are routed on a second internal layer, e.g., internal layer 40(2).

First plated-through vias 94 are provided to route secondary signals to and from the bottom layer 30 and internal layer 40(2). These secondary signals are then routed by signal lines on internal layer 40(2) to second plated-through vias 96 and transported to and from the top layer 20. In one embodiment, several, e.g., four (4) of the longest high-speed primary northbound (PN) differential signal lines are routed in this manner on internal layer 40(1)in stripline form. For any line spacing, there is less crosstalk between signal lines that are implemented in stripline than microstrip.

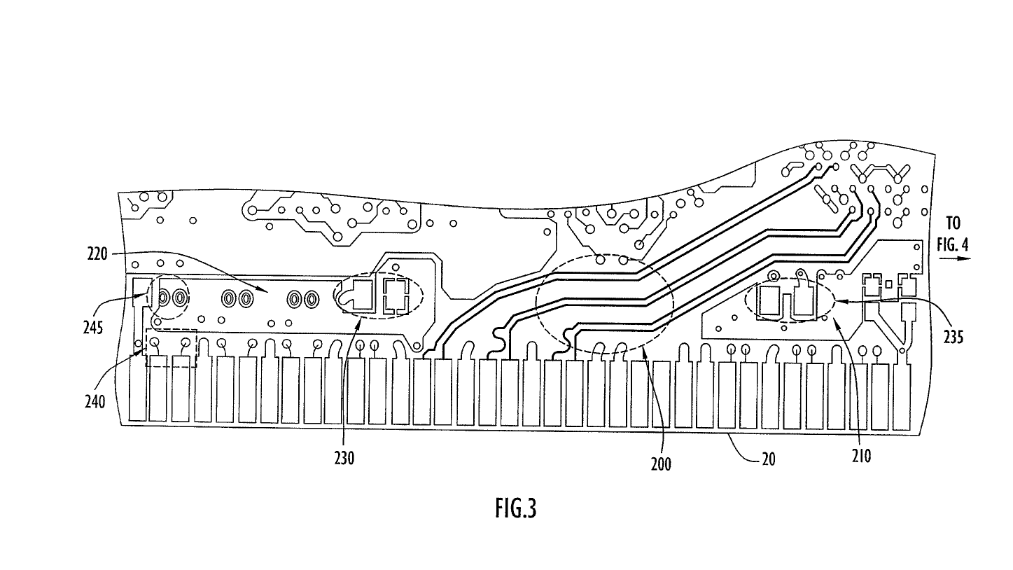

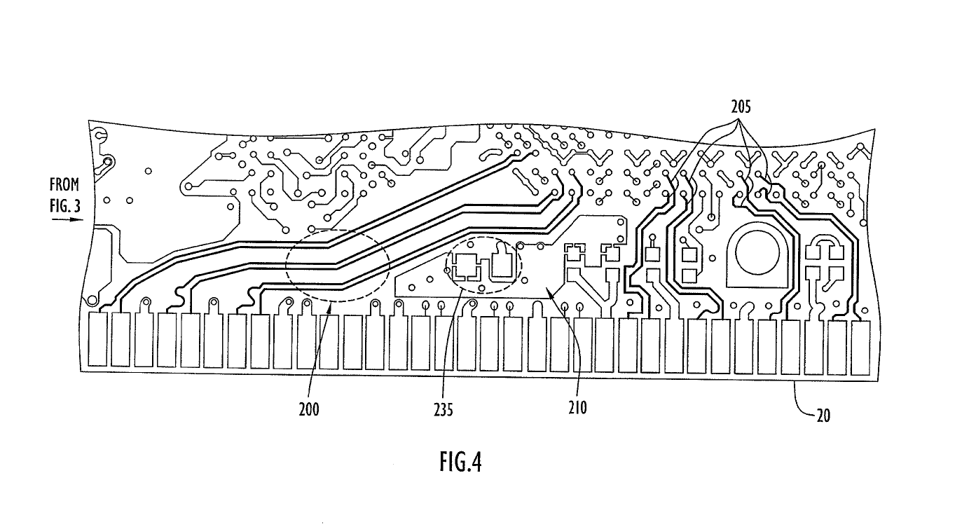

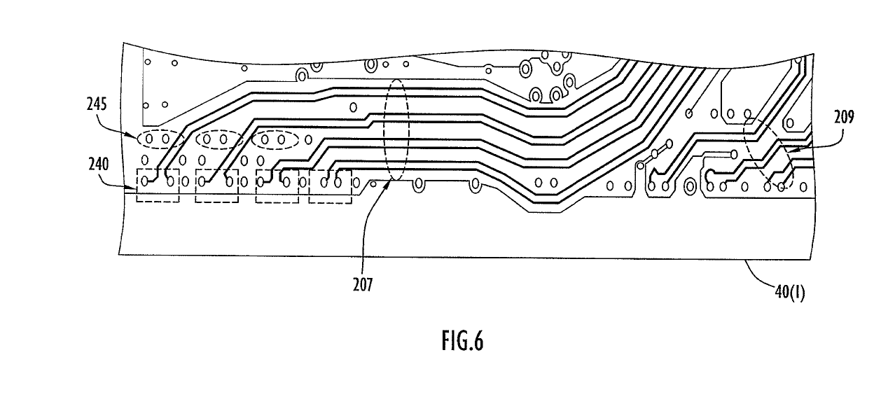

FIGS. 3-5 are enlarged partial images of a top layer 20 of a PCB 10 employing the signal line routing technique to an embodiment of the invention. The signals lines for PN signals that remain on the top layer 20 are shown at 200 in FIGS. 3 and 4. In this exemplary embodiment, the signals lines 200 are differential lines (pairs of signal lines). The longer signal lines for the PN signals are routed on the internal layer 40(1) and described in further detail hereinafter in conjunction with FIG. 6. Additional signal lines for PN signals routed on the top layer 20 are shown at 205. Signal lines 205 are relatively shorter in length and therefore may be routed on the top layer 20 with little spacing impact and timing budget impact. Also shown on the top layer in one embodiment are additional power supply (Vcc) planes 210 and 220. Within the region of the power supply plane 210 is a decoupling capacitor 235 and within the region of power supply plane 220 is a decoupling capacitor 230.

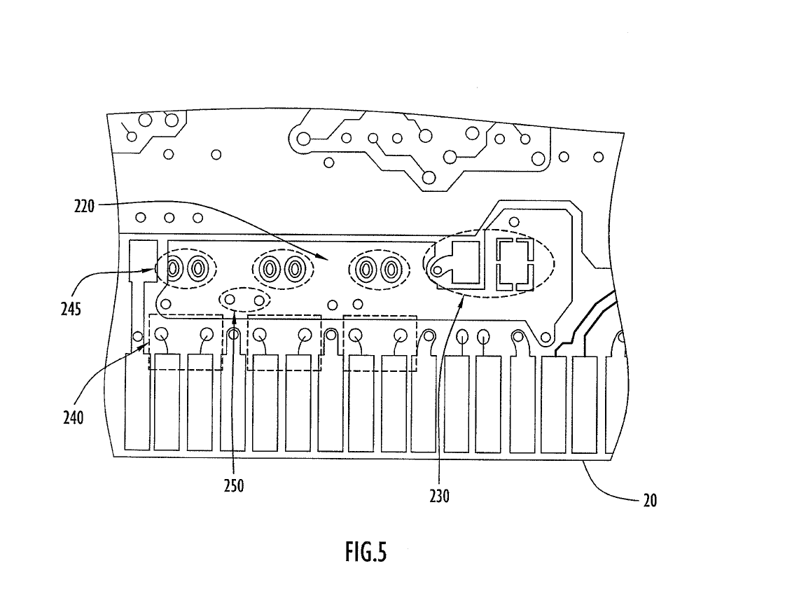

FIG. 5 is an enlarged view of a portion of the top layer shown in FIG. 3 and better shows the additional power supply plane 220 and surrounding elements. The top end portions of the blind vias 90 (FIG. 1) for primary (e.g., PN) signals are shown at 240 and the top end portions of plated-through vias 94 (FIG. 1) for secondary (e.g., SN) signals are shown at 245 within a region of the power supply plane 220. In addition, the top end portions of power supply vias are shown at reference numeral 250 within the power supply plane 220.

The top end portions 240 of the PN vias are spaced from the top end portions 245 of the SN vias in an arrangement referred to as a “far side-by-side constellation”. This arrangement achieves adequate separation between the PN vias and the SN vias even though they are present on at least a portion of the same layer, e.g., internal layer 40(2) as shown in FIG. 1.

Because some of the longer signal lines are moved from the top layer 20 to an internal layer, e.g., internal layer 40(1), more space is available on the top layer 20 for the additional power supply planes 210 and 220, thus providing for placement of vias for SN signal lines in a region within the power supply plane 220 and spaced from the vias for PN signal lines. The decoupling capacitors (coupled to ground) in the power supply planes 210 and 220 serve to reduce noise. Thus, the additional power supply planes 210 and 220 enhance delivery of power supply and serves as a place for decoupling capacitors. The power supply plane 220 also serves as isolation between the SN vias and PN vias.

Furthermore, since fewer signal lines are routed on the top layer 20, the signal lines that are on the top layer 20 can be sufficiently spaced from each other. In one embodiment, the signal lines for differential PN signals (3 pairs of them shown in FIGS. 3 and 4) can be spaced by as much as 0.5 mm, for example, greater than would otherwise be possible with the conventional signal routing schemes. In addition, these lines can stay on the top layer 20 in microstrip form because their channel lengths are not too long (e.g., up to 21 mm in one embodiment). The PN differential signal line pairs selected for implementation on the top layer 20 in microstrip are those that are not critical to impact of the timing budget of the device.

Reference is now made to FIG. 6 for a description of the internal layer 40(1) according to one embodiment. Several of the (longest in physical length) signal lines for PN signals shown at 207 are routed in the internal layer 40(1) in stripline form. In the exemplary embodiment shown in FIG. 6, there are four differential signal line pairs for PN signals that are routed in stripline form on the internal layer 40(1). The spacing between pairs of these lines can be made to minimize or prevent crosstalk between them. The PN vias 240 to the signal lines 207 and the SN vias 245 are shown on the left of FIG. 6. There are also additional signal lines for PN signals shown at 209 on the lower right of FIG. 6.

In sum, the signal routing technique described herein reduces crosstalk by moving the longest signal bus lines to an internal layer of a multilayered PCB where the lines can be made in stripline as opposed to microstrip. This technique allows for maximizing the spacing between higher speed signal lines on a multilayered PCB to minimize or eliminate crosstalk between those signal lines and achieve better differential impedance tolerance. Space is also made available for additional Vcc planes with decoupling capacitors and Vcc vias. The Vcc plane and the Vcc vias in the Vcc plane further isolate PN vias from SN vias. Also, improved power supply access is provided by the additional Vcc planes in the top layer. While the signal routing techniques have been described herein as being useful in a DIMM, they are applicable and useful in any type of multilayered printed circuit board device that may require routing of signal lines to minimize crosstalk between them.

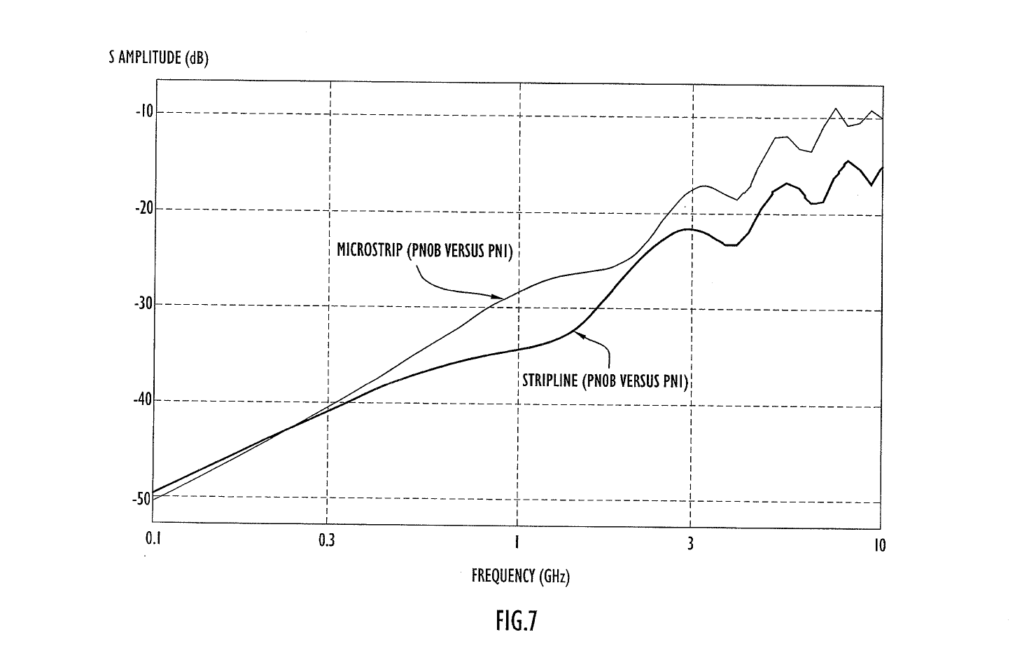

Turning to FIG. 7, a comparison of simulation results are shown for two adjacent high speed signal lines (e.g., lines (PN0B) and PN1) implemented in stripline according to the embodiments of the present invention and implemented in microstrip. This figure shows that these signal lines at the connector area exhibit reduced crosstalk characteristics at high frequencies (3-10 GHz) when implemented in stripline according to the embodiments of the invention, despite the potential for via-to-via crosstalk at the connector area between them.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A circuit board, comprising:
a. a top layer, a bottom layer and at least one internal layer;
b. lines for a first subset of higher speed signals being routed on said internal layer, wherein the lines for said first subset of the higher speed signals are longer in physical length among the lines for said plurality of higher speed signals; and
c. partial vias making connection to said lines for the first subset of higher speed signals on said internal layers, said partial vias extending between said internal layer and said top layer.

2. The circuit board of claim 1, wherein the lines for said first subset of the plurality of higher speed signals are in stripline on said internal layer.

3. The circuit board of claim 2, and further comprising lines for a second subset of said plurality of higher speed signals routed on said top layer in microstrip.

4. The circuit board of claim 3, wherein the lines for said second subset of said plurality of higher speed signals are shorter in physical length than the lines for said first subset of higher speed signals.

5. A multilayered circuit board, comprising:
a. a top layer, a bottom layer and at least a first internal layer;
b. signal lines for a first subset of a plurality of higher speed buses implemented in stripline on said first internal layer; and
c. signal lines for a second subset of said plurality of higher speed buses implemented in microstrip on said top layer.

6. The circuit board of claim 5, and further comprising a second internal layer, and signal lines for a third subset of said plurality of higher speed signals being routed on said second internal layer.

7. The circuit board of claim 6, and further comprising plated-through vias extending between the top layer and the bottom layer, said plated-through vias making electrical connection with said signals lines for said third subset of the plurality of higher speed buses on said second internal layer.

8. The circuit board of claim 7, wherein said signal lines for said third subset of the plurality of higher speed buses extending from a first area on said second internal layer where connection is made to first plated-through vias to a second area on said second internal layer where connection is made to second plated-through vias.

9. The circuit board of claim 5, and further comprising partial vias making electrical connection to the signals for said first subset of the plurality of higher speed buses on said first internal layer, said partial vias extending between said first internal layer and said top layer.

10. The circuit board of claim 9, wherein said signal lines for said first subset of the plurality of higher speed buses extending from a first area on said first internal layer where connected is made to first partial vias to a second area on said first internal layer where connection is made to second plated-through vias.

11. The circuit board of claim 9, and further comprising at least one power supply plane on said top layer and at least one decoupling capacitor positioned within a region of and connected to said power supply plane.

12. The circuit board of claim 11, wherein end portions of the partial vias at the top layer are positioned in a region outside of said power supply plane.

13. The circuit board of claim 12, and further comprising a second internal layer, and signal lines for a third subset of said plurality of higher speed signals being routed on said second internal layer; and plated-through vias extending between the top layer and the bottom layer, said plated-through vias making electrical connection with said signals lines for said third subset of the plurality of higher speed buses on said second internal layer, wherein end portions of the plated-through vias at said top layer being positioned within a region of said power supply plane.

14. The circuit board of claim 13, and further comprising power supply vias extending from said top layer into said circuit board, and wherein end portions of said power supply vias at said top layer are positioned between end portions of the plated-through vias and end portions of said partial vias.

15. A system comprising a plurality of multilayered circuit boards according to claim 5 and a device controller, wherein said plurality of multilayered circuit boards are arranged in daisy-chain organization and wherein one of said plurality of multilayered circuit boards is connected to said device controller.

16. A method for routing signals on a multilayered circuit board having a top layer, bottom layer and at least a first internal layer, comprising:
a. routing signals for a first subset of a plurality of higher speed buses in stripline on the first internal layer; and
b. routing signals for a second subset of said plurality of higher speed buses in microstrip on the top layer.

17. The method of claim 16, and further comprising routing signal lines for a third subset of said plurality of higher speed signals on a second internal layer.

18. The method of claim 17, and further comprising communicating said signals for the third subset of higher speed buses between said second internal layer and said top layer and between said second internal layer and said bottom layer by vias that extend from the top layer to the bottom layer.

19. The method of claim 18, and further comprising communicating said signals for the first subset of higher speed buses between said top layer and said first internal layer by vias extending between the top layer and said first internal layer.

20. The method of claim 16, wherein (a) routing comprises routing the signals for the first subset of higher speed buses on conductive lines that are longer in length than conductive lines used for routing the signals for the second subset of higher speed buses on the top layer.
